(19) United States
(12) Patent Application Publication
(10) Pub. No.: US 2011/0006753 A1
(43) Pub. Date: Jan. 13, 2011

(54) ELECTRIC CURRENT SENSOR

(75) Inventors: Konghui YU, Niiza-shi (JP); Masakazu Kobayashi, Fukaya-shi (JP)

Correspondence Address: DAY PITNEY LLP, 7 TIMES SQUARE, NEW YORK, NY, 10036-7311, US

(73) Assignee: TAMURA CORPORATION, Tokyo (JP)

(21) Appl. No.: 12/833,090

(22) Filed: Jul. 9, 2010

(30) Foreign Application Priority Data
Jul. 9, 2009 (JP) JP2009-162401

(51) Int. Cl. G01R 19/00

(52) U.S. Cl. 324/117 R

(57) ABSTRACT

An electric current sensor, including a circular magnetic material core, an excitation coil wound around the magnetic material core, a supplemental excitation coil wound around the magnetic material core, a first excitation circuit that applies an alternating excitation voltage to the excitation coil, a second excitation circuit that applies pulsed voltages synchronized with rising edges and lowering edges of the excitation voltage, the pulsed voltages causing the supplemental coil generate magnetic fields having the same directions as that of the magnetic fields generated by the excitation coil, a current-to-voltage converter that converts a current flows through the excitation coil into a voltage, and a detection unit that detects respective timings when the alternating magnetic field in the magnetic material core is saturated in a positive direction and in a negative direction.

### BACKGROUND OF THE INVENTION

The present invention relates to a fluxgate-type electric current sensor which is used as a sensor for detecting an electrical leakage in an electronic device, such as a solar power generation system or an air conditioner.

Conventionally, from the viewpoint of safety operation (e.g., to detect an electrical leakage), an electric current sensor has been used to measure a direct electric current in an electronic device in which a direct electric current is used. A fluxgate-type electric current sensor (hereinafter, simply referred to as “electric current sensor”) has been often used, since it can be used at ordinary temperatures and it can be easily downsized and super-sensitized, and it has a high magnetic susceptibility to an infinitesimal magnetic field. Such an electric current sensor is disclosed, for example, in Japanese Patent Provisional Publications No. HEI 07-128373A and No. 2000-2738A.

FIG. 6 shows a schematic configuration of a conventional electric current sensor. In general, an electric current sensor includes a circular soft magnetic material core 21 made of a high magnetic permeability material, such as permalloy, an excitation coil 22 wound up around a perimeter of the core 21, an oscillating circuit 23 which applies an excitation voltage to the excitation coil 22, a current-to-voltage converter 24 which transforms a current flowing through the excitation coil 22 into a voltage, and a comparator 25. A conducting wire 30, through which a current to be measured flows, is disposed such that the conducting wire 30 passes through the core 21.

FIG. 7 is a timing chart illustrating operation of an electric current sensor shown in FIG. 6. FIG. 7 shows waveforms of an excitation voltage, a detected electric current, and an output from a comparator, respectively, when there is no electric current flowing through the conductive wire 30. Further, a graph shown in upper-right portion of FIG. 7 is a magnetic hysteresis loop showing a B-H characteristic of the excitation coil 22. The oscillating circuit 23 applies a rectangular alternating-current signal of a predetermined frequency to the excitation coil 22 as an excitation voltage. At this time, the core 21 is excited so that the core 21 having the B-H characteristic shown in FIG. 7 is sufficiently magnetically saturated. The current-to-voltage converter 24 detects an electric current flowing through the excitation coil 22, transforms the detected electric current into a voltage and outputs the voltage to the comparator 25. Here, since the excitation coil 22 has an inductance in a region where the core 21 is not saturated, the detected electric current increases or decreases substantially linearly. In a region where the core 21 is saturated, since the inductance of the excitation coil 22 decreases, a large electric current flows and the waveform becomes substantially a pulse (spike) waveform. The comparator 25 detects a position of a pulse directed to the plus direction and a position of a pulse directed to the minus direction, from the output of the current-to-voltage converter 24. Namely, the comparator 25 inverts its output from plus to minus, when the comparator 25 detects a rising edge of a positive pulse. Successively, the comparator 25 inverts its output from minus to plus, when the comparator 25 detects a lowering edge of a negative pulse. Therefore, when there is no electric current on the conductive wire 30, a time, t1, from a positive pulse to a negative pulse is equal to a time, t2, from a negative pulse to a positive pulse. Thus, the output from the comparator 25 is a rectangular-wave signal with a duty cycle of 50% having the same frequency as that of the excitation voltage.

FIG. 8 is a timing diagram illustrating an operation of the electric current sensor shown in FIG. 6. FIG. 8 shows respective waveforms, when an electric current is flowing through the conductive wire 30 in a positive direction (the direction indicated by an arrow in FIG. 6). When the electric current flows through the conductive wire 30 in the positive direction, the B-H curve of the core 21 shows a characteristic such that the B-H curve is shifted by a positive magnetic field +ΔH generated by the conductive wire 30. Namely, when the oscillating circuit 23 applies a rectangular alternating-current signal of a predetermined frequency to the excitation coil 22 as an excitation voltage, the core 21 shows a characteristic such that the core 21 is easily saturated if the magnetic field is applied in the positive direction, and the core 21 is not easily saturated if the magnetic field is applied in the negative direction. Therefore, the time, t1, from a positive pulse to a negative pulse becomes longer than the time, t2, from a negative pulse to a positive pulse. Thus, the output from the comparator 25 has the same frequency as that of the excitation voltage and has the duty cycle of t2/(t1+t2), (where t1>t2). Further, since the generated magnetic field +ΔH is proportional to the electric current flowing through the conductive wire 30, the duty cycle of the output signal from the comparator 25 shows the amount and the direction of the electric current flowing through the conductive wire 30.

FIG. 9 is a timing diagram illustrating an operation of the electric current sensor shown in FIG. 6. FIG. 9 shows respective waveforms, when an electric current is flowing through the conductive wire 30 in a negative direction (the direction opposite to the direction indicated by the arrow in FIG. 6). When the electric current flows through the conductive wire 30 in the negative direction, the B-H curve of the core 21 shows a characteristic such that the B-H curve is shifted by a negative magnetic field −ΔH generated by the conductive wire 30. Namely, when the oscillating circuit 23 applies a rectangular alternating-current signal of a predetermined frequency to the excitation coil 22 as an excitation voltage, the core 21 shows a characteristic such that the core 21 is not easily saturated if the magnetic field is applied in the positive direction, and the core 21 is easily saturated if the magnetic field is applied in the negative direction. Therefore, the time, t1, from a positive pulse to a negative pulse becomes shorter than the time, t2, from a negative pulse to a positive pulse. Thus, the output from the comparator 25 has the same frequency as that of the excitation voltage and has the duty cycle of t2/(t1+t2), (where t1<t2). Further, since the generated magnetic field −ΔH is proportional to the electric current flowing through the conductive wire 30, the duty cycle of the output signal from the comparator 25 shows the amount and the direction of the electric current flowing through the conductive wire 30.

As described above, the electric current sensor can output a direction and a value of an electric current flowing through the conductive wire 30 by utilizing the characteristic that the B-H curve of the core 21 is shifted by a magnetic field generated by a current flowing through the conductive wire 30.

### SUMMARY OF THE INVENTION

Fluxgate-type electric current sensors have been mainly used for detecting direct electric currents, but not widely used for detecting alternating electric currents. This is attributable to a configuration of the electric current sensor that a direction and a value of an electric current flowing through the conductive wire 30 is detected based on a time difference between a time required for the core 21 to be saturated in a positive direction and a time required for the core 21 to be saturated in a negative direction. The frequency of an excitation voltage cannot be raised to such a high frequency that allows a detection of an alternating electric current. The core 21 of the electric current sensor has a predetermined B-H characteristic which is mainly determined by a material. When a core 21 having a B-H curve with a low gradient (i.e., having a low magnetic permeability) is used, a time-lag between a time when the excitation voltage is applied and a time when the core 21 is saturated becomes greater. Since this time-lag regulates the frequency of the excitation voltage, when a core 21 having a B-H curve with a low gradient is used, the frequency of the excitation voltage cannot be raised to such a high frequency that allows a detection of an alternating electric current. Further, it is possible to use a magnetic material core having an excellent rectangular shape characteristic for the B-H curve1, such as cobalt base amorphous alloy. However, a magnetic material having an excellent rectangular shape characteristic is usually expensive.

The present invention has been achieved to solve the above described problem. The present invention is advantageous in that it provides an electric current sensor capable of detecting both an alternating current and a direct current by raising a frequency of an excitation voltage with a simple configuration.

According to an aspect of the invention, there is provided an electric current sensor for detecting a direction and an amount of an electric current to be measured flowing through a conductive wire. The electric current censor comprises a circular magnetic material core having an opening at a center portion of the magnetic material core, the conductive wire passing through the opening; an excitation coil wound around the magnetic material core; a supplemental excitation coil wound around the magnetic material core; a first excitation circuit that applies a rectangular wave shaped alternating excitation voltage of a predetermined frequency to the excitation coil, the alternating excitation voltage causing the excitation coil saturate an alternating magnetic field in the magnetic material core, both in a positive direction and in a negative direction; a second excitation circuit that applies a positive pulsed voltage and a negative pulsed voltage to the supplemental excitation coil, the positive pulsed voltage and the negative pulsed voltage being synchronized with a rising edge and a lowering edge of the alternating excitation voltage, respectively, so as to align a direction of a magnetic field generated by the supplemental coil with a direction of a magnetic field generated by applying the alternating excitation voltage to the excitation coil; a current-to-voltage converter that converts an excitation current flowing through the excitation coil into a voltage and outputs a detected voltage; and a detection unit that detects a timing when the alternating magnetic field in the magnetic material core is saturated in the positive direction and a timing when the alternating magnetic field in the magnetic material core is saturated in the negative direction, respectively, based on the detected voltage. In this configuration, the timings when the alternating magnetic field in the magnetic material core is saturated in the positive direction and in the negative direction correspond to the direction and the amount of the electric current to be measured. With such a configuration, the frequency of the excitation voltage can be raised with a simple configuration, thereby allowing to provide an electric current sensor which can detect both an alternating electric current and a direct electric current.

In at least one aspect, the positive pulsed voltage and the negative pulsed voltage applied to the supplemental excitation coil may have pulse widths shorter than a saturation time required when the alternating magnetic field in the magnetic material core is saturated only with the excitation coil. With such a configuration, the time required for the core to be saturated can be certainly shortened without interfering with sensitivity of the electric current sensor.

In at least one aspect, the second excitation circuit may comprise: a first switch element that applies the positive pulsed voltage; a second switch element that applies the negative pulsed voltage; and a switching circuit. In this case, the switching circuit controls the first switch element and generates the positive pulsed voltage when the switching circuit detects a rising edge of the alternating excitation voltage, and the switching circuit controls the second switch element and generates the negative pulsed voltage when the switching circuit detects a lowering edge of the alternating excitation voltage. With such a configuration, the frequency of the excitation voltage can be raised with a simple configuration.

In at least one aspect, the detection unit may include a comparator that inverts an output state based on the timing when the alternating magnetic field in the magnetic material core is saturated in the positive direction and the timing when the alternating magnetic field in the magnetic material core is saturated in the negative direction. With such a configuration, a saturation timing can be certainly detected.

In at least one aspect, the electric current sensor may further include a low-pass filter which averages an output signal from the comparator. With such a configuration, subsequent processes become easier:

In at least one aspect, the electric current sensor may further include an amplifier which determines a difference between an output from the low-pass filter and a predetermined reference voltage. With such a configuration, subsequent processes become easier.

### BRIEF DESCRIPTION OF THE ACCOMPANYING DRAWINGS

FIG. 1 is a block diagram illustrating a general configuration of an electric current sensor according to an embodiment of the invention.

FIG. 2 is a circuit diagram of the electric current sensor according to the embodiment of the invention.

FIG. 3 is a timing diagram illustrating an operation of the electric current sensor when there is no current flowing through a conductive wire.

FIG. 4 is a timing diagram illustrating an operation of the electric current sensor when an electric current flows through the conductive wire in a positive direction.

FIG. 5 is a timing diagram illustrating an operation of the electric current sensor when an electric current flows through the conductive wire in a negative direction.

FIG. 6 is a block diagram illustrating a configuration of a conventional electric current sensor.

FIG. 7 is a timing diagram illustrating an operation of a conventional electric current sensor when there is no electric current flowing through a conductive wire.

FIG. 8 is a timing diagram illustrating an operation of a conventional electric current sensor when an electric current is flowing through the conductive wire in a positive direction.

FIG. 9 is a timing diagram illustrating an operation of a conventional electric current sensor when an electric current is flowing through the conductive wire in a negative direction.

### DETAILED DESCRIPTION OF THE EMBODIMENTS

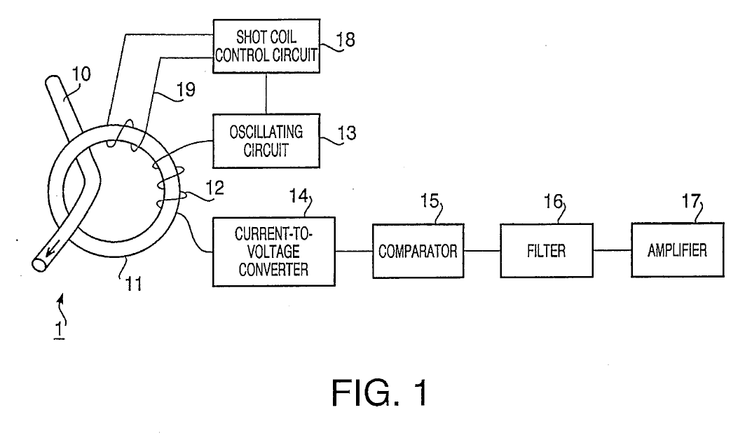

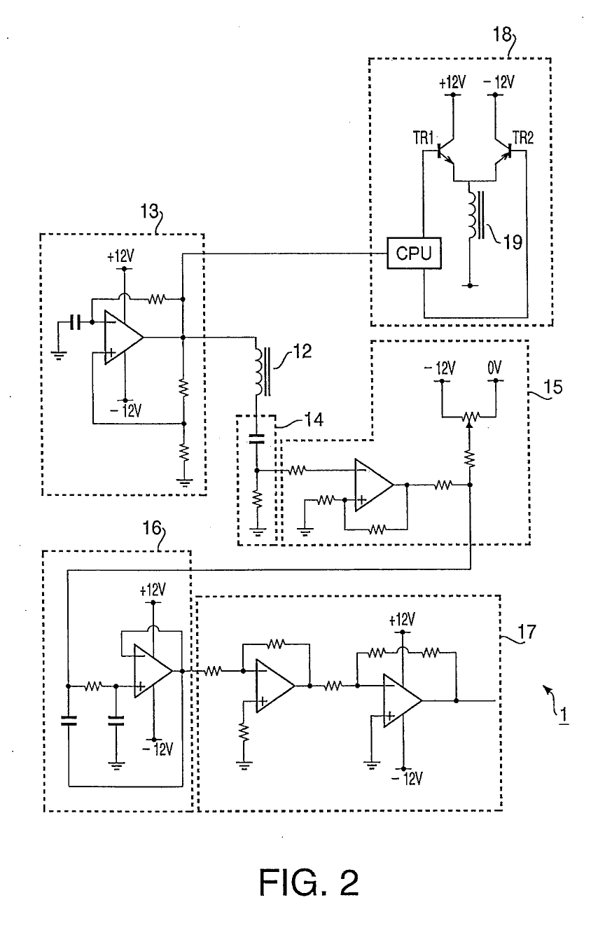

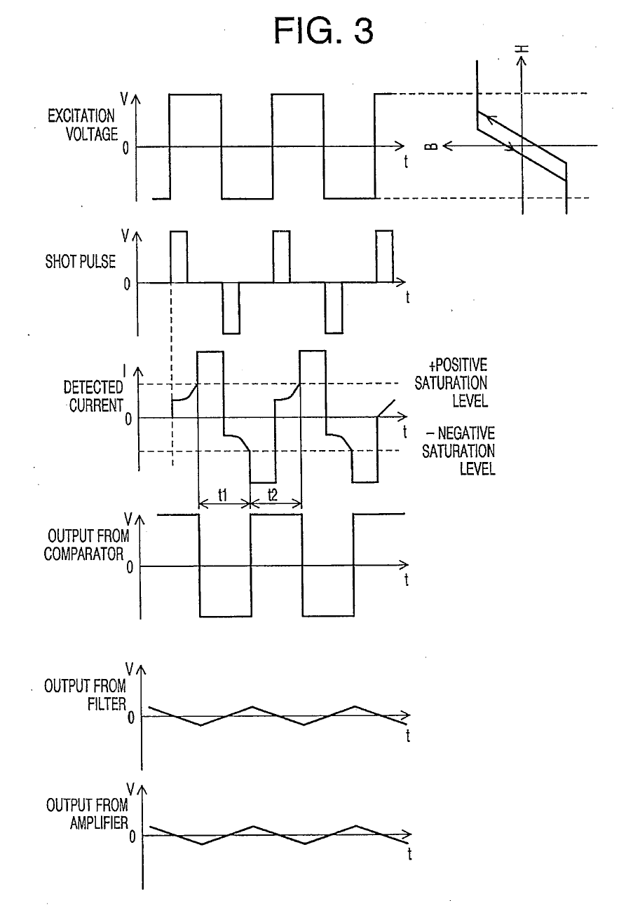

An electronic current sensor according to an embodiment of the present invention is explained below. FIG. 1 is a block diagram illustrating a general configuration of an electric current sensor 1 according to an embodiment of the invention. FIG. 2 is a circuit diagram of the electric current sensor 1. FIG. 3 is a timing diagram illustrating respective waveforms when there is no current flowing through a conductive wire 10 in FIG. 1. Here, the same reference numeral is assigned to each configuration common to respective figures.

The electric current sensor 1 according to the embodiment of the present invention includes a core 11, an excitation coil 12, an oscillating circuit 13, a current-to-voltage converter 14, a comparator 15, a filter 16, an amplifier 17, a shot coil control circuit 18, and a shot coil 19. A conducting wire 10 through which a current to be measured flows is disposed such that the conducting wire 10 passes through the core 11.

The core 11 is a circular soft magnetic material core made of a high magnetic permeability material (e.g., permalloy). The core 11 has an opening at a center portion thereof, through which the conductive wire 10 passes.

The excitation coil 12 is wound around (3000-5000 turns) the core 11 to form a toroidal shape. One end of the excitation coil 12 is connected to the oscillating circuit 13, and the other end of the excitation coil 12 is connected to the current-to-voltage converter 14. An alternating excitation electric current flows when an alternating excitation electric voltage is applied from the oscillating circuit 13 to the excitation coil 12, thereby exciting the core 11.

The oscillating circuit 13 (a first excitation circuit) is a circuit which applies a rectangular alternating-current signal of a predetermined frequency (e.g., 2 kHz-4 kHz) to the excitation coil 12 as an alternating excitation voltage. The alternating excitation voltage has, depending on a B-H characteristic of the core 11, an amplitude large enough to cause magnetic fields in a positive direction and in a negative direction in the core 11 (an alternating magnetic field) to be sufficiently magnetically saturated (FIG. 3). Further, the oscillating circuit 13 is connected to the shot coil control circuit 18 and the rectangular alternating-current signal is also supplied to the shot coil control circuit 18. In this embodiment, the oscillating circuit 13 is configured with an operational amplifier.

The shot coil 19 is wound around (for example, 3-5 turns) the core 11 to form a toroidal shape, and one end of the shot coil 19 is connected to an emitter of an NPN transistor, TR1, and an emitter of an PNP transistor, TR2, in the shot coil control circuit 18, and the other end of the shot coil 19 is connected to the ground electric potential. The shot coil 19 generates a magnetic field in the core 11, when it is applied a pulse shaped voltage (a shot pulse) from the shot coil control circuit 18. Namely, the shot coil 19 functions as a supplemental excitation coil.

The shot coil control circuit 18 (the second excitation circuit) includes an NPN transistor TR1 (a first switch element), a PNP transistor TR2 (a second switch element) and a switch control circuit CPU. The switch control circuit CPU receives a rectangular alternating-current signal from the oscillating circuit 13 and generates synchronizing pulses synchronized with the rectangular alternating-current signal. The switch control circuit CPU controls the NPN transistor, TR1, and the PNP transistor, TR2, using the synchronizing pulses and applies positive or negative shot pulses to the shot coil 19. Specifically, the switch control circuit CPU generates positive synchronizing pulses of duration corresponding to a duty cycle of 20% synchronized with the rising edges of the rectangular alternating-current signal. The switch control circuit CPU inputs the positive synchronizing pulses to the base of the NPN transistor, TR1, thereby setting the NPN transistor, TR1, to ON. When the NPN transistor, TR1, is set to ON, a voltage (+12V) connected to the collector of the NPN transistor, TR1, is applied to the shot coil 19 as a positive shot pulse. Further, the shot coil control circuit 18 generates negative synchronizing pulses of duration corresponding to a duty cycle of 20% synchronized with the lowering edges of the rectangular alternating-current signal. The shot coil control circuit 18 inputs the negative synchronizing pulses to the base of the PNP transistor, TR2, thereby setting the PNP transistor, TR2, to ON. When the PNP transistor, TR2, is set to ON, a voltage (−12V) connected to the collector of the PNP transistor, TR2, is applied to the shot coil 19 as a negative shot pulse. Therefore, during a time period corresponding to a duration of a duty cycle of 20% after rising of the excitation voltage, the excitation coil 12 and the shot coil 19 simultaneously excite a magnetic field in the core 11 in a positive direction. During a time period corresponding to a duration of a duty cycle of 20% after lowering of the excitation voltage, the excitation coil 12 and the shot coil 19 simultaneously excite a magnetic field in the core 11 in a negative direction. Consequently, the timing of saturating the magnetic field in the positive direction in the core 11 and the timing of saturating the magnetic field in the negative direction are shortened. An electric current flowing through the excitation coil 12, namely a detected electric current, has substantially a pulse waveform as in the case of a detected electric current of a conventional electric current sensor, but the detected electric current is observed as a waveform which is offset in the positive direction when the detected electric current switches from negative to positive, and which is offset in the negative direction when the detected electric current switches from positive to negative (see FIG. 3).

The current-to-voltage converter 14 detects an electric current flowing through the excitation coil 12 and converts the electric current to a voltage, for example, by using a resistor. The detected voltage is output to the comparator 15.

The comparator 15 (a detection unit) detects a position of a pulse in the positive direction and a position of a pulse in the negative direction, namely, a timing when the alternating magnetic field in the core 11 is saturated in the positive direction and a timing when the alternating magnetic field in the core 11 is saturated in the negative direction, on the output from the current-to-voltage converter 14. When the comparator 15 detects a rising edge of a positive pulse (when the magnetic field is saturated in the positive direction), the output from the comparator switches from positive to negative, and when the comparator 15 detects a lowering edge of a negative pulse (when the magnetic field is saturated in the negative direction), the output from the comparator switches from negative to positive. The duty cycle of the output signal from the comparator 15 is a signal representing an amount and a direction of an electric current flowing through the conductive wire 10, as in the case of a conventional electric current sensor. In the case of FIG. 3, since there is no current flowing through the conductive wire 10, the output signal has a waveform with a duty cycle of 50%. In this embodiment, the comparator 15 is a comparator made of an operational amplifier and the comparator 15 has a hysteresis characteristic.

The filter 16 is a low-pass filter for averaging (integrating) the output from the comparator 15. In this embodiment, the filter 16 is a second order low-pass filter including an operational amplifier, a resistor, and a capacitor. Values of the resistor and the capacitor determine the cut-off frequency of the low-pass filter, and these values differ depending on how the electric current sensor 1 is used. A relatively long time constant is selected for detecting a direct electric current, and a short time constant responsive to the frequency of an alternating waveform is selected for detecting an alternating electric current, so as to enable sufficient sampling of an alternating waveform to be detected. The filter 16 converts a current flowing through the conductive wire 10 into an analog voltage, thereby making it easier to perform subsequent processes.

The amplifier 17 determines a difference between an output from the filter 16 and a reference voltage (e.g., 0V), then applies a predetermined gain to the output from the filter 16 and outputs the result. In this embodiment, the amplifier 17 includes an error amplifier for determining a difference between an input voltage and a reference voltage (0V), and an inverting amplifier for inverting and amplifying an output from the error amplifier. The amplifier 17 converts an electric current flowing through the conductive wire 10 into an analog voltage having a predetermined amplitude with respect to a predetermined reference voltage, thereby making it easier to perform subsequent processes.

In this embodiment, a duty cycle of an output signal of the comparator 15 represents a direction and an amount of an electric current flowing through the conductive wire 10, as in the case of a conventional electric current sensor. Thus, an output from the subsequent filter 16 and an output from the amplifier 17 are, indeed, signals representing the direction and the amount of the electric current. The output from the amplifier 17 is operated and processed by an external circuit or a device, not shown in figures, thereby enabling a measurement of a value of the electric current. Further, in FIG. 3, since there is no electric current flowing through the conductive wire 10, an output from the filter 16 and an output from the amplifier 17 are observed as small triangular waves centered at 0V.

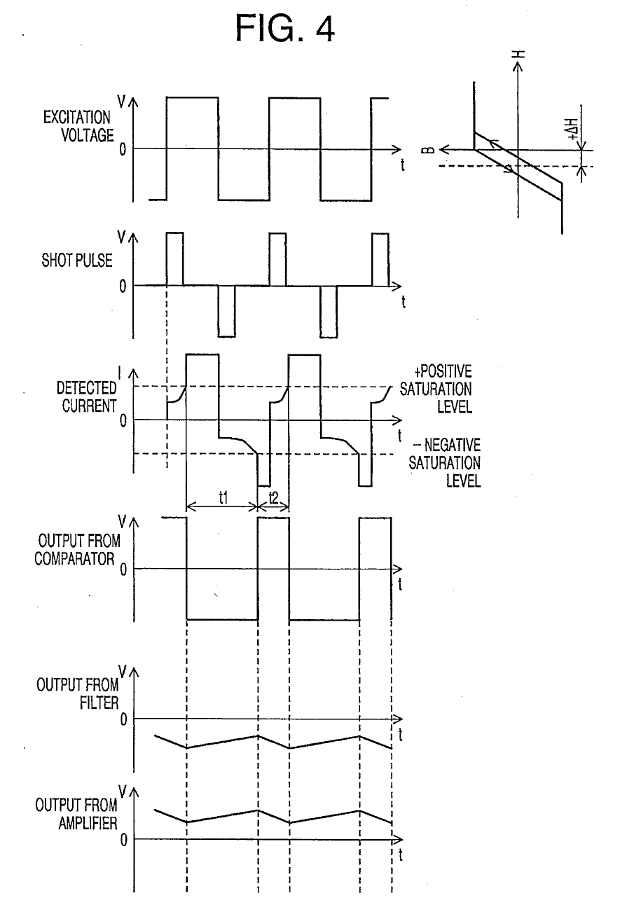

FIG. 4 is a timing diagram illustrating respective waveforms when an electric current flows through the conductive wire 10, shown in FIG. 1, in the positive direction (the direction indicated by the arrow in FIG. 1).

When a current flows through the conductive wire 10 in the positive direction, the B-H characteristic of the core shows a characteristic which is shifted by a positive magnetic field +ΔH generated by the conductive wire 10. Namely, when the oscillating circuit 13 applies a rectangular alternating-current signal of a predetermined frequency to the excitation coil 12 as an excitation voltage, the characteristic becomes such that a magnetic field is easily saturated when the magnetic field is applied in the positive direction, and a magnetic field is not easily saturated when the magnetic field is applied in the negative direction. Therefore, the time, t1, from a positive pulse to a negative pulse becomes longer than the time, t2, from a negative pulse to a positive pulse. The output from the comparator 15 has the same frequency as that of the excitation voltage and a duty cycle of t2/(t1+t2), (where t1>t2). The output from the filter 16, which is a result of averaging the output from the comparator 15, is observed as a saw wave oscillating within a negative voltage range. Further, the output from the filter 16 is inverted and amplified by the amplifier 17, and observed as a saw wave oscillating within a positive voltage range.

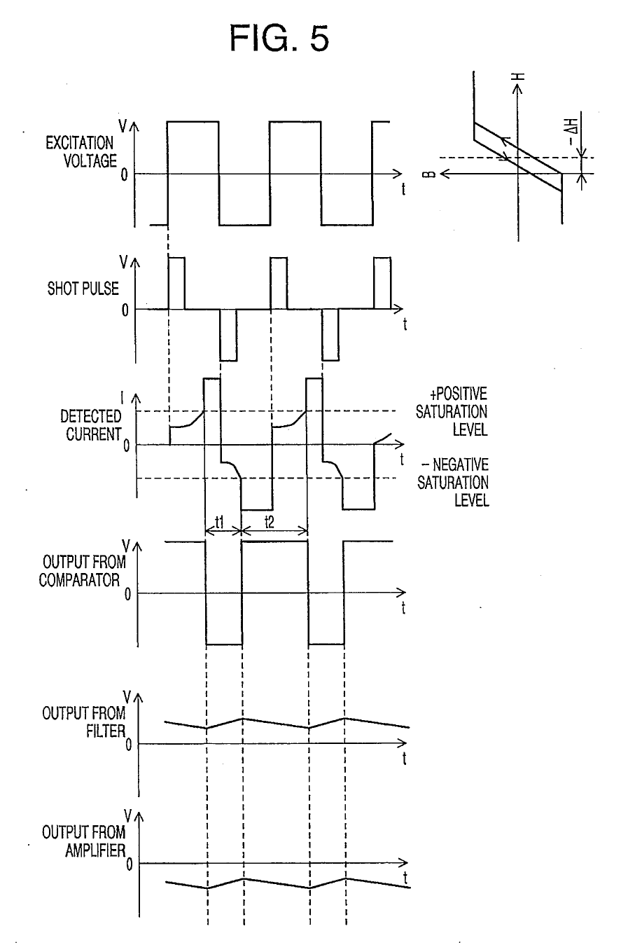

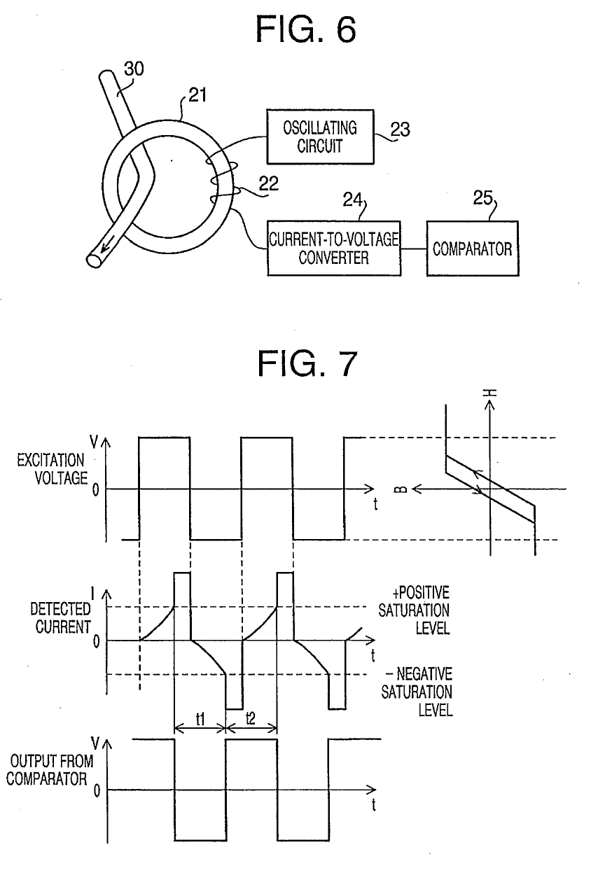

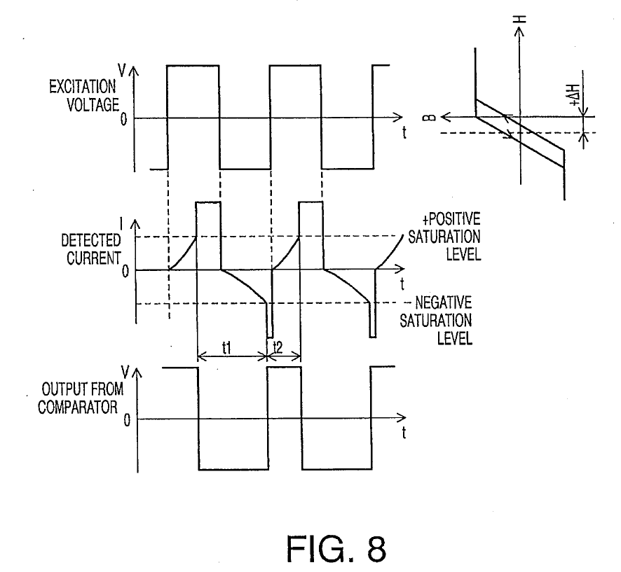

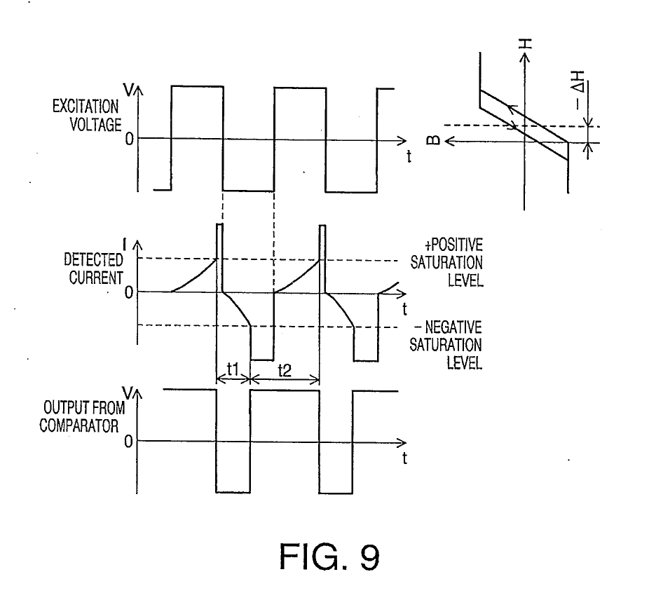

FIG. 5 is a timing diagram illustrating respective waveforms when an electric current flows through the conductive wire 10, shown in FIG. 1, in the negative direction (the direction opposite to the direction indicated by the arrow in FIG. 1).

When a current flows through the conductive wire 10 in the negative direction, the B-H characteristic of the core 11 shows a characteristic which is shifted by a negative magnetic field −ΔH generated by the conductive wire 10. Namely, when the oscillating circuit 13 applies a rectangular alternating-current signal of a predetermined frequency to the excitation coil 12 as an excitation voltage, the characteristic becomes such that a magnetic field is not easily saturated when the magnetic field is applied in the positive direction, and a magnetic field is easily saturated when the magnetic field is applied in the negative direction. Therefore, the time, t1, from a positive pulse to a negative pulse becomes shorter than the time, t2, from a negative pulse to a positive pulse. The output from the comparator 15 has the same frequency as that of the excitation voltage and a duty cycle of t2/(t1+t2), (where t1<t2). The output from the filter 16, which is a result of averaging the output from the comparator 15, is observed as a saw wave oscillating within a positive voltage range. Further, the output from the filter 16 is inverted and amplified by the amplifier 17, and observed as a saw wave oscillating within a negative voltage range.

As described above, in the electric current sensor 1 according to this embodiment, the excitation coil 12 and the shot coil 10 simultaneously excite a magnetic field in the core at a predetermined timing, thereby shortening the time required for the core 11 to be saturated. Thus, the frequency of the excitation voltage can be raised by the amount corresponding to the shortened amount of the time required for the core 11 to be saturated, thereby enabling detection of not only a direct electric current but also an alternating electric current. Further, it becomes possible to use an inexpensive core which has a B-H curve whose gradient is smaller (i.e., having a low magnetic permeability) than that of a B-H curve of a core which have been used for a conventional electric current sensor.

In this embodiment, a pulse width of a shot pulse is explained to be a duty cycle of 20% with respect to a frequency of a rectangular alternating-current signal, but the pulse width is not limited to this embodiment. A pulse width of a shot pulse can be any time period shorter than the minimum value of a saturation time required to saturate a magnetic field in the core 11 after inputting the excitation voltage, when the magnetic field in the core 11 is saturated only with the excitation coil 12. Namely, a saturation time required differs depending on the amount of an electric current flowing through the conductive wire 10. The minimum saturation time required (e.g., corresponding to a duty cycle of 25%) is the saturation time required when the maximum permissible electric current value for the electric current sensor 1 is detected. If a pulse width of a shot pulse is shorter than the minimum saturation time required, the time required for saturation can be certainly shortened without interfering with the original sensitivity of the electric current sensor 1. Further, depending on a gradient of a B-H curve of a core being used, a pulse width of a shot pulse can be changed properly, within the range up to the minimum saturation time required. Since the core is saturated more quickly when a pulse width of a shot pulse is lengthened, it is advantageous to lengthen a pulse width of a shot pulse when an inexpensive core is used.

Further, shot pulses according to this embodiment are explained to be positive shot pulses synchronized with rising edges of a rectangular alternating-current signal and negative shot pulses synchronized with lowering edges of the rectangular alternating-current signal, but shot pulses are not limited to this embodiment. Namely, it suffices if the direction of a magnetic field generated by the excitation coil 12 and the direction of a magnetic field generated by the shot coil 19 are the same. For example, when the direction of winding of the excitation coil 12 and that of the shot coil 19 are different, shot pulses are positive shot pulses synchronized with lowering edges of a rectangular alternating-current signal and negative pulses synchronized with rising edges of the rectangular alternating-current signal.

The shot coil control circuit 18 according to this embodiment includes the NPN transistor, TR1, the PNP transistor, TR2, and the switch control circuit CPU, but the shot coil control circuit 18 is not limited to this embodiment. For example, an analog switch can be used instead of a transistor. A timing switching circuit CPU can be configured with a timer circuit and an analog switch.

Further, the filter 16 according to this embodiment is explained to be a second order low-pass filter, but the filter 16 is not limited to this embodiment. The filter 16 can be a first order low-pass filter including a resistor and a capacitor.

This application claims priority of Japanese Patent Application No. 2009-162401, filed on Jul. 9, 2009. The entire subject matter of the application is incorporated herein by reference.

What is claimed is:

1. An electric current sensor for detecting a direction and an amount of an electric current to be measured flowing through a conductive wire, comprising:
a circular magnetic material core having an opening at a center portion of the magnetic material core, the conductive wire passing through the opening;
an excitation coil wound around the magnetic material core;
a supplemental excitation coil wound around the magnetic material core;
a first excitation circuit that applies a rectangular wave shaped alternating excitation voltage of a predetermined frequency to the excitation coil, the alternating excitation voltage causing the excitation coil saturate an alternating magnetic field in the magnetic material core, both in a positive direction and in a negative direction;
a second excitation circuit that applies a positive pulsed voltage and a negative pulsed voltage to the supplemental excitation coil, the positive pulsed voltage and the negative pulsed voltage being synchronized with a rising edge and a lowering edge of the alternating excitation voltage, respectively, so as to align a direction of a magnetic field generated by the supplemental coil with a direction of a magnetic field generated by applying the alternating excitation voltage to the excitation coil;
a current-to-voltage converter that converts an excitation current flowing through the excitation coil into a voltage and outputs a detected voltage; and
a detection unit that detects a timing when the alternating magnetic field in the magnetic material core is saturated in the positive direction and a timing when the alternating magnetic field in the magnetic material core is saturated in the negative direction, respectively, based on the detected voltage,
wherein the timings when the alternating magnetic field in the magnetic material core is saturated in the positive direction and in the negative direction correspond to the direction and the amount of the electric current to be measured.

2. The electric current sensor according to claim 1, wherein the positive pulsed voltage and the negative pulsed voltage have pulse widths shorter than a saturation time required when the alternating magnetic field in the magnetic material core is saturated only with the excitation coil.

3. The electric current sensor according to claim 1,
wherein the second excitation circuit comprises:
a first switch element that applies the positive pulsed voltage;
a second switch element that applies the negative pulsed voltage; and
a switching circuit,
wherein the switching circuit controls the first switch element and generates the positive pulsed voltage when the switching circuit detects a rising edge of the alternating excitation voltage, and the switching circuit controls the second switch element and generates the negative pulsed voltage when the switching circuit detects a lowering edge of the alternating excitation voltage.

4. The electric current sensor according to claim 1, wherein the detection unit includes a comparator that inverts an output state based on the timing when the alternating magnetic field in the magnetic material core is saturated in the positive direction and the timing when the alternating magnetic field in the magnetic material core is saturated in the negative direction.

5. The electric current sensor according to claim 4, further comprising a low-pass filter which averages an output signal from the comparator.

6. The electric current sensor according to claim 5, further comprising an amplifier which determines a difference between an output from the low-pass filter and a predetermined reference voltage.

7. The electric current sensor according to claim 2, wherein the detection unit includes a comparator that inverts an output state based on the timing when the alternating magnetic field in the magnetic material core is saturated in the positive direction and the timing when the alternating magnetic field in the magnetic material core is saturated in the negative direction.

8. The electric current sensor according to claim 3, wherein the detection unit includes a comparator that inverts an output state based on the timing when the alternating magnetic field in the magnetic material core is saturated in the positive direction and the timing when the alternating magnetic field in the magnetic material core is saturated in the negative direction.
